(19) United States
(12) Patent Application Publication
(10) Pub. No.: US 2013/0279132 A1
(43) Pub. Date: Oct. 24, 2013

(54) ELECTROMAGNETIC SHIELDING COVER

(71) Applicants: SHIH-PO LO, NEW TAIPEI CITY (TW); TAN-LUNG CHEN, NEW TAIPEI CITY (TW); CHING-FENG HSIEH, TAIPEI CITY (TW)

(72) Inventors: SHIH-PO LO, NEW TAIPEI CITY (TW); TAN-LUNG CHEN, NEW TAIPEI CITY (TW); CHING-FENG HSIEH, TAIPEI CITY (TW)

(73) Assignees: ASKEY COMPUTER CORP.; ASKEY TECHNOLOGY (JIANGSU) LTD.

(21) Appl. No.: 13/542,135

(22) Filed: Jul. 5, 2012

(30) Foreign Application Priority Data
Apr. 24, 2012 (TW) 101207595

(51) Int. Cl. H05K 5/04

(52) U.S. Cl. 361/757; 361/752

(57) ABSTRACT

An electromagnetic shielding cover disposed on a printed circuit board having thereon an electronic component includes a lid and a frame which are coupled together to shield the electronic component from electromagnetic interference and allow the electronic component to be changed and tested easily during a rework process.

### CROSS-REFERENCE TO RELATED APPLICATION

This non-provisional application claims priority under 35 U.S.C. §119(a) on Patent Application No(s).101207595 filed in Taiwan, R.O.C. on Apr. 24, 2012, the entire contents of which are hereby incorporated by reference.

### FIELD OF TECHNOLOGY

The following relates to electromagnetic shielding covers, and more particularly, to an electromagnetic shielding cover for shielding an electronic component.

### BACKGROUND

Electronic devices are often susceptible to electromagnetic interference (EMI), and in consequence the performance of the electronic devices deteriorates. Examples of conventional electronic devices include smart mobile phones, tablet computers, and portable computers. As shown in FIG. 1, a shielding casing is a conventional tool of blocking EMI. The shielding casing essentially comprises a shielding frame 6 and a shielding cover 8. An assembly process of the shielding casing comprises the steps of: having a plurality of positioning holes 32 formed on a printed circuit board 3 with an electronic component 5 mounted thereon and positioned in a manner to surround the electronic component 5; providing the shielding frame 6 having a plurality of pins 62; passing the pins 62 through the positioning holes 32, respectively, and fastening the pins 62 through the positioning holes 32, respectively, to allow the printed circuit board 3 and the shielding frame 6 to be coupled together; and coupling the shielding cover 8 and the shielding frame 6 together so as to form the shielding casing for blocking EMI. A plurality of dents 64 (or bumps) is formed on the surface of the shielding frame 6. A plurality of bumps 82 (or dents) is formed on the surface of the shielding cover 8. The dents 64 correspond in position to the bumps 82, respectively. Coupling the dents 64 and the bumps 82 together results in the coupling together of the shielding frame 6 and the shielding cover 8.

To test or change the electronic component 5 of the printed circuit board 3, it is necessary to disassemble the shielding casing. The disassembly process of the shielding casing necessitates performing the aforesaid assembly process in reverse order. However, when carried out repeatedly or with an inappropriate applied force, the disassembly process of the shielding casing is likely to end up in deformation of the shielding cover 8, thereby preventing the reuse of the shielding cover 8 and incurring costs. Once the shielding cover 8 is rendered not usable for the aforesaid reasons, it is necessary to redesign and mold a new shielding cover, thereby adding to the manufacturing costs.

Accordingly, it is imperative to provide an electromagnetic shielding cover to not only shield an electronic component of an electronic device from EMI but also change the electronic component at low costs.

### SUMMARY

It is an objective of the present invention to provide an electromagnetic shielding cover for shielding an electronic component from EMI.

Another objective of the present invention is to provide an electromagnetic shielding cover for changing and testing an electronic component easily. Yet another objective of the present invention is to provide an electromagnetic shielding cover for cutting the manufacturing costs of a shielding casing.

In order to achieve the above and other objectives, the present invention provides an electromagnetic shielding cover disposed on a printed circuit board having thereon an electronic component. The electromagnetic shielding cover comprises a frame and a lid. The frame is coupled to the printed circuit board and has an opening for exposing the electronic component. The lid is removably coupled to the frame to cover the frame and closes the opening, thereby allowing the electromagnetic shielding cover to shield the electronic component.

Compared with the prior art, the present invention provides an electromagnetic shielding cover comprising a frame and a lid which are coupled together to shield an electronic component on a printed circuit board from electromagnetic interference (EMI) and allow the electronic component to be changed and tested easily and at a low cost.

### BRIEF DESCRIPTION OF THE DRAWINGS

Objectives, features, and advantages of the present invention are hereunder illustrated with specific embodiments in conjunction with the accompanying drawings, in which:

FIG. 1 (PRIOR ART) is a schematic view of assembly of a shielding cover and a printed circuit board;

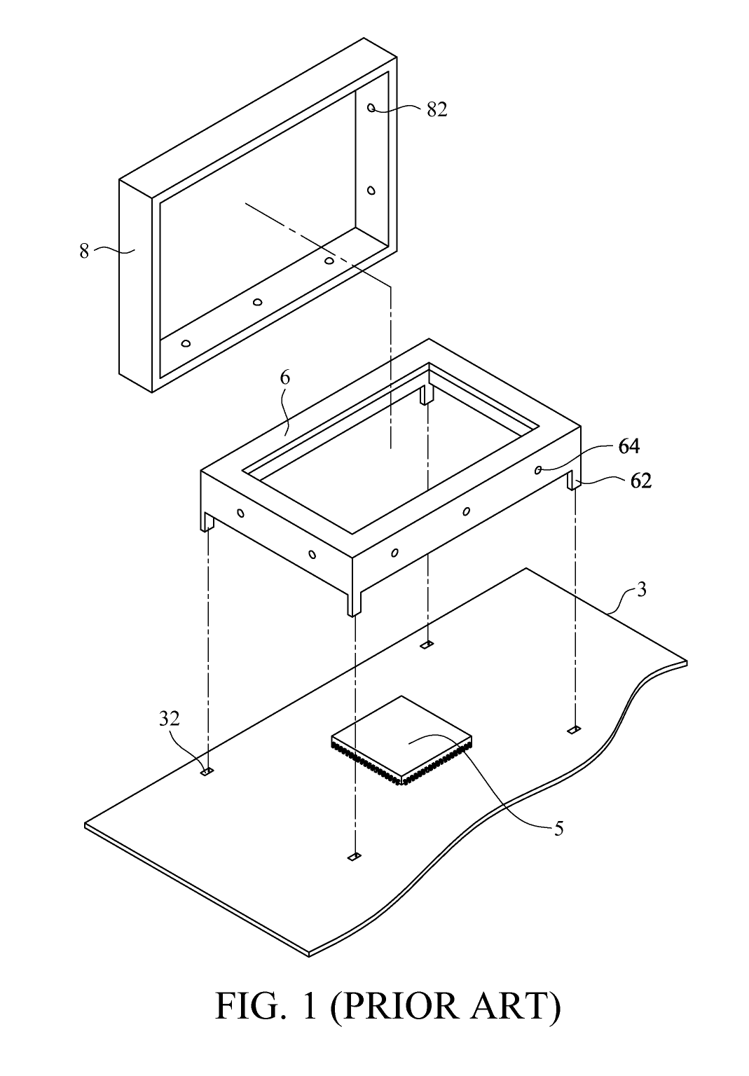

FIG. 2 is an exploded schematic view of an electromagnetic shielding cover according to the first embodiment of the present invention;

FIG. 3 is a perspective view of the electromagnetic shielding cover of FIG. 2 when assembled;

FIG. 4 is an exploded schematic view of an electromagnetic shielding cover according to the second embodiment of the present invention;

FIG. 5 is a partial structural schematic view of an adhesive layer according to the second embodiment of the present invention; and

FIG. 6 is a schematic view of assembly of the electromagnetic shielding cover and the printed circuit board of FIG. 4 according to the third embodiment of the present invention.

### DETAILED DESCRIPTION

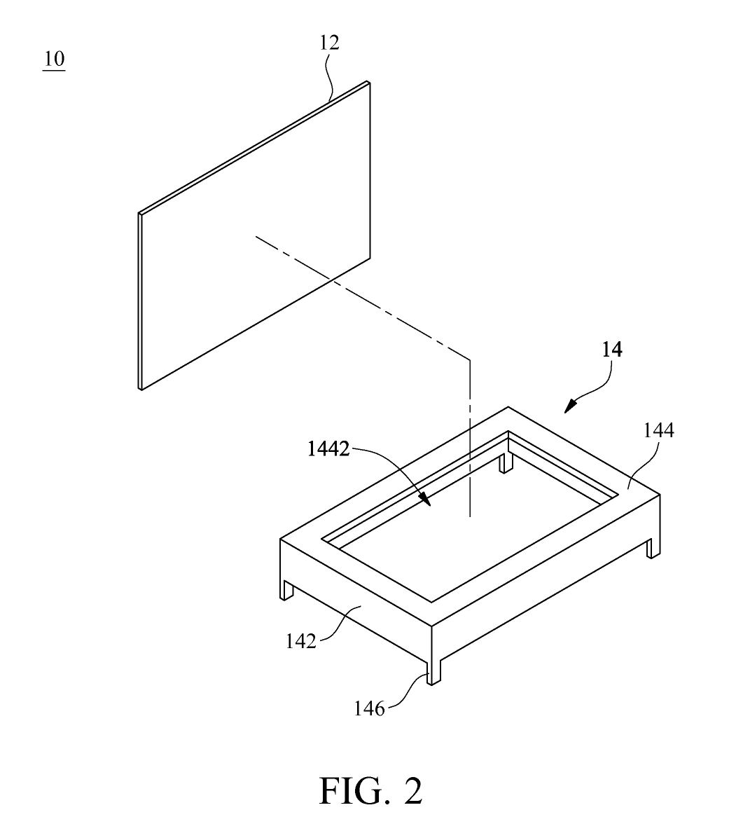

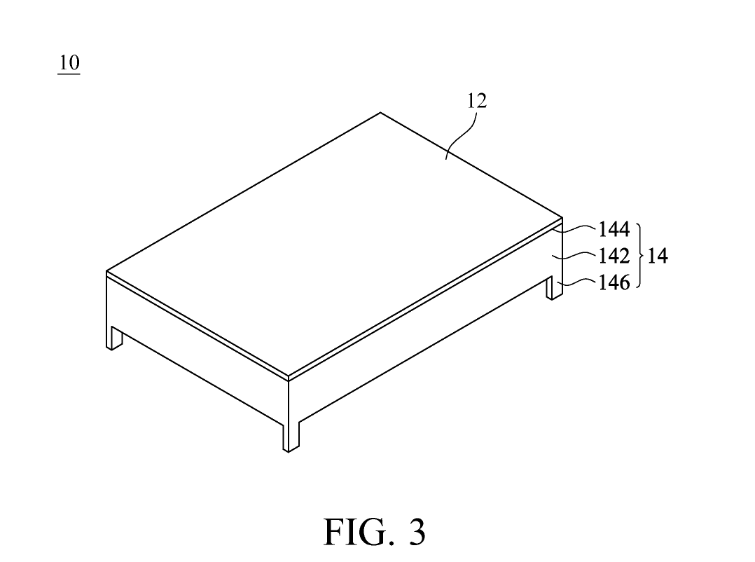

Referring to FIG. 2 and FIG. 3, there are shown an exploded schematic view and a perspective view of an electromagnetic shielding cover 10 according to the first embodiment of the present invention. As shown in FIG. 2, the electromagnetic shielding cover 10 comprises a lid 12 and a frame 14. The electromagnetic shielding cover 10 is disposed on a printed circuit board (not shown) on which an electronic component (not shown) and a plurality of positioning holes (not shown) are disposed.

The frame 14, which is coupled to the printed circuit board, comprises a frame body 142, a coupling portion 144, a fixing portion 146, and an opening 1442. The frame body 142, the coupling portion 144, and the fixing portion 146 are either integrally formed as a unitary structure or provided separately and then combined. In this embodiment, the frame body 142, the coupling portion 144, and the fixing portion 146 are integrally formed as a unitary structure to serve an illustrative purpose. The frame body 142 can come in any shape, provided that the frame body 142 encloses the electronic component mounted on the printed circuit board. The opening 1442 is defined by the frame body 142. In this embodiment, the opening 1442 has a rectangular profile just to serve an illustrative purpose. As a result, the frame body 142 also has a rectangular profile.

The lid 12 is removably coupled to the frame 14 to cover the frame 14 and thereby close the opening 1442, such that the electromagnetic shielding cover 10 can shield the electronic component. The lid 12 is plate-shaped and is made of a metal, such as copper, aluminum, or tin. In practice, the lid 12 is made from a copper foil, an aluminum foil, or a tin foil.

### DEFINITIONS

The terms “upper surface” and “lower surface” are hereinafter referred to those of an electronic component having multiple sides, wherein the adjectives “upper” and “lower” serve to distinguish the surfaces from each other.

The coupling portion 144 is formed on the upper surface of the frame body 142, such that the frame 14 is coupled to the lid 12 via the coupling portion 144. The coupling portion 144 defines the opening 1442, such that the electronic component on the printed circuit board is exposed from the opening 1442 as soon as the frame 14 and the printed circuit board are coupled together. The area of the lid 12 is larger than the area of the opening 1442.

The opening 1442 can be formed in two different ways. First, the coupling portion 144 is punched and penetrated to form the opening 1442 (wherein, before the punching process, the coupling portion 144 is plate-like rather than frame-like, and rests on the upper surface of the frame body 142). Second, the opening 1442 and the coupling portion 144 are integrally formed as a unitary structure. Although one said opening 1442 is shown in FIG. 2, the quantity of the opening 1442 should not be limited thereto but should be subject to changes as needed, provided that the electronic component is exposed from the opening 1442.

The fixing portion 146 is formed on the lower surface of the frame body 142 and adapted to allow the frame body 142 to be fixed to the printed circuit board, such that the electronic component mounted on the printed circuit board is positioned proximate to the frame 14. The fixing portion 146 comes in the form of pins or surface mounted devices (SMD) whereby the frame 14 can be mounted on or dismounted from the printed circuit board easily. In this embodiment, the fixing portion 146 comes in the form of a plurality of pins extending from the frame body 142. The pins correspond in position, quantity, and shape to the positioning holes on the printed circuit board.

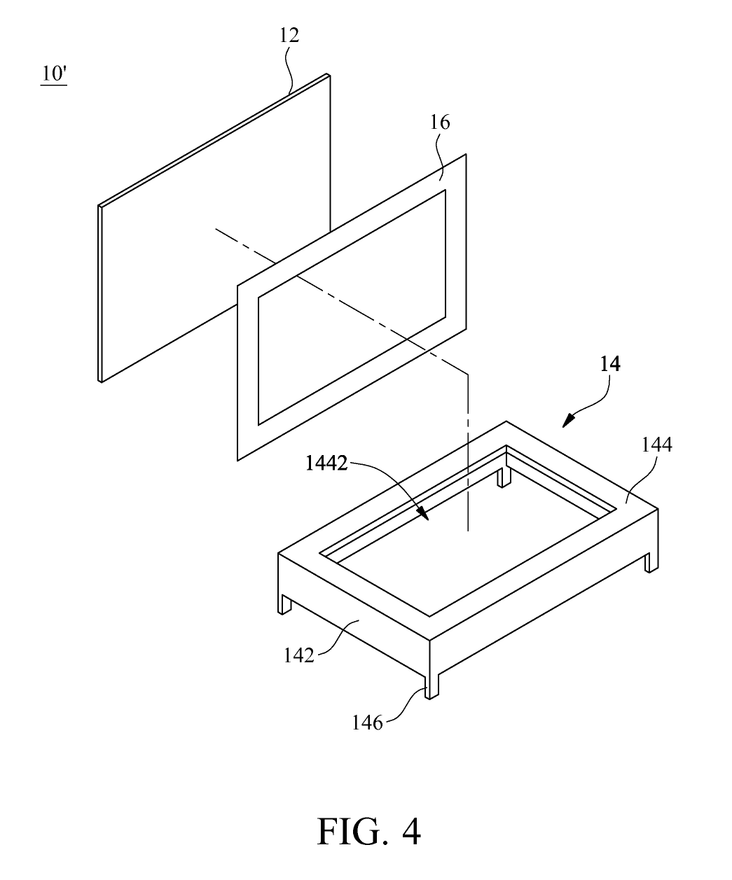

Referring to FIG. 4, there is shown an exploded schematic view of an electromagnetic shielding cover 10′ according to the second embodiment of the present invention. As shown in FIG. 4, the electromagnetic shielding cover 10′ comprises the lid 12, the frame 14, and an adhesive layer 16. The second embodiment is different from the first embodiment in that, in the second embodiment, the electromagnetic shielding cover 10′ further comprises the adhesive layer 16. The adhesive layer 16 is disposed between the coupling portion 144 of the frame 14 and the lid 12 and adapted to allow the lid 12 to be adhered and coupled to the frame 14, such that the lid 12 closes the opening 1442, thereby allowing the electronic component to be shielded against electromagnetic interference (EMI).

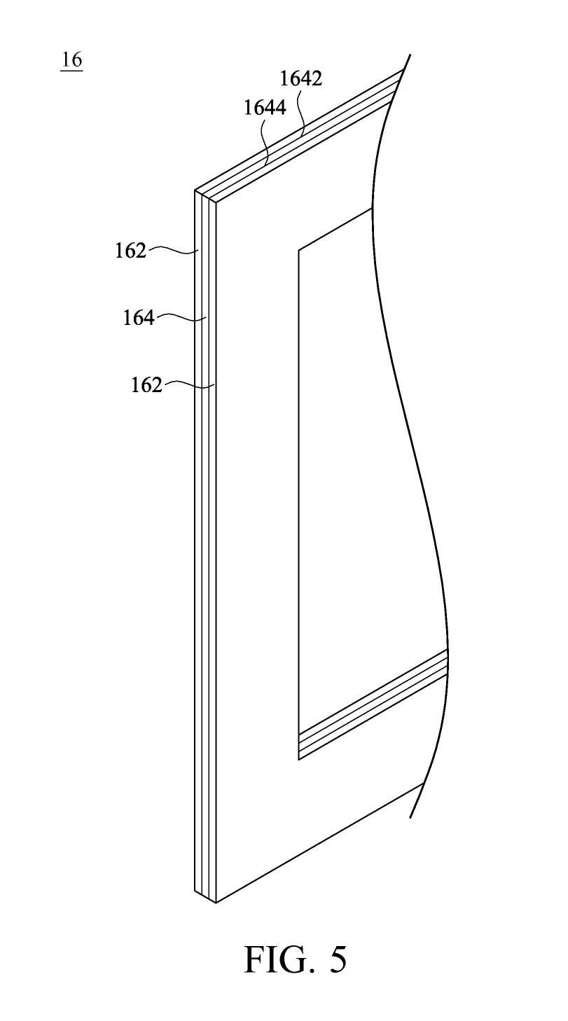

Referring to FIG. 5, there is a partial structural schematic view of the adhesive layer 16 according to the second embodiment of the present invention. As shown in FIG. 5, the adhesive layer 16 further comprises a plurality of release papers 162 and an adhesive body 164. The release papers 162 are disposed on a first surface 1642 of the adhesive body 164 and a second surface 1644 of the adhesive body 164, respectively, wherein the first surface 1642 is opposite to the second surface 1644. Referring to FIG. 4 and FIG. 5, the first surface 1642 of the adhesive body 164 is adhered to the lid 12 or the coupling portion 144 of the frame 14 in advance, and then the second surface 1644 of the adhesive body 164 is adhered to the release papers 162. After the release papers 162 have been peeled off the adhesive body 164, the lid 12 can be adhered to the frame 14. A point to note is that the adhesive layer 16 is not only applicable to the release papers 162 and the adhesive body 164 in this embodiment, but can also come in the form of adhesive glue that can be applied to the lid 12 or the coupling portion 144. That is to say, the adhesive layer 16 of the present invention can work well, as long as the adhesive layer 16 enables the tight coupling of the lid 12 and the frame 14 and enables the lid 12 to cover the opening 1442.

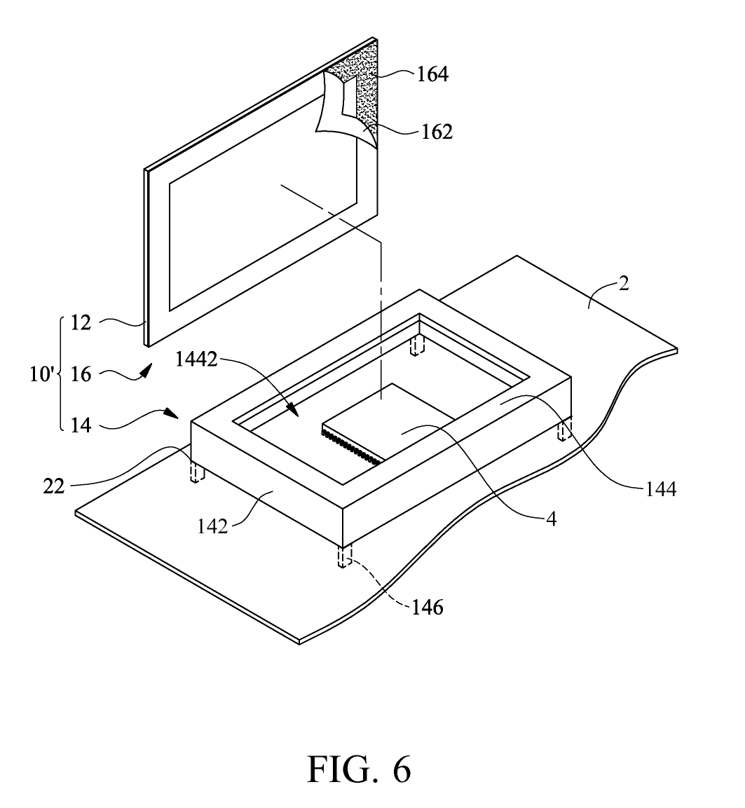

Referring to FIG. 6, there is shown a schematic view of assembly of the electromagnetic shielding cover and the printed circuit board of FIG. 4 according to the third embodiment of the present invention. As shown in FIG. 6, the electromagnetic shielding cover 10′ provides EMI shielding for an electronic component 4 on a printed circuit board 2 having a plurality of positioning holes 22.

In this embodiment, the adhesive body 164 of the adhesive layer 16 shown in FIG. 5 is adhered to the lid 12 in advance. The release paper 162 is disposed on the other side of the adhesive body 164 as opposed to the side adhered to the lid 12. The release paper 162 of the adhesive layer 16 is to be peeled off by the user, such that the adhesive body 164 is exposed to allow the lid 12 to be adhered to the frame 14. With the fixing portion 146 that comes in the form of a plurality of pins, the frame 14 can be engaged with the positioning holes 22 of the printed circuit board 2, and then the pins are bent or soldered to the printed circuit board 2, so as to allow the frame 14 to be fixed to the printed circuit board 2. When fixed in place, the frame body 142 encloses the electronic component 4.

Furthermore, the coupling portion 144 on the frame body 142 has the opening 1442, such that the electronic component 4 can be exposed from the opening 1442, thereby allowing the user to change or test the electronic component 4 directly.

After the lid 12 having the adhesive body 164 has been adhered to the coupling portion 144 of the frame 14, the lid 12 can completely cover the opening 1442, such that the electronic component 4 is accommodated in the shielding space jointly formed by the frame 14 and the lid 12 which are coupled together. Hence, the electromagnetic shielding cover 10′ is effective in shielding the electronic component 4 from EMI.

To change or test the electronic component 4, it is only necessary to remove the lid 12 from the frame 14 rather than remove both the lid 12 and the frame 14.

A shielding test is performed at an electromagnetic wave frequency of 30 MHz-1 GHz on three scenarios, namely the electromagnetic shielding cover of the present invention, a conventional shielding casing, and the absence of any shielding structure. The result of the shielding test indicates that, compared with the scenario of the absence of any shielding structure, the electromagnetic shielding cover of the present invention is as effective as the conventional shielding casing in EMI shielding.

Compared with the prior art, an electromagnetic shielding cover of the present invention, so as to form a shielding space for receiving therein an electronic component mounted on a printed circuit board as soon as a lid and a frame of the electromagnetic shielding cover are coupled together for shielding the electronic component from electromagnetic interference (EMI), thereby allowing the electronic component to be changed and tested easily and at a low cost.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. An electromagnetic shielding cover disposed on a printed circuit board having thereon an electronic component, the electromagnetic shielding cover comprising:
a frame coupled to the printed circuit board and having an opening for exposing the electronic component; and
a lid removably coupled to the frame to cover the frame and close the opening, thereby allowing the electromagnetic shielding cover to shield the electronic component.

2. The electromagnetic shielding cover of claim 1, wherein the lid is made from a metal foil of one of copper, aluminum, and tin.

3. The electromagnetic shielding cover of claim 1, wherein the lid has a larger area than the opening does.

4. The electromagnetic shielding cover of claim 1, wherein the frame is adhered and fixed to the printed circuit board and positioned proximate to the electronic component.

5. The electromagnetic shielding cover of claim 1, wherein the frame has a plurality of pins extending from a lower surface of the frame.

6. The electromagnetic shielding cover of claim 1, further comprising an adhesive layer disposed between the frame and the lid to allow the lid to be adhered and coupled to the frame.

7. The electromagnetic shielding cover of claim 6, wherein the adhesive layer further comprises a plurality of release papers and an adhesive body, the release papers being disposed on a first surface and a second surface of the adhesive body, respectively, the second surface opposing the first surface.
